(19) United States
(12) Patent Application Publication
(10) Pub. No.: US 2010/0101624 A1
(43) Pub. Date: Apr. 29, 2010

(54) PHOTOVOLTAIC MODULE AND MODULAR PANEL MADE WITH IT TO COLLECT RADIANT SOLAR ENERGY

(76) Inventors: Emanuela Fioretti, Castelfidardo (IT); Tommaso Virnicchi, Recanati (IT)

Correspondence Address: HODES PESSIN & KATZ PA, 901 Dulaney Valley Road, Suite 400, Towson, MD, 21204, US

(21) Appl. No.: 12/452,194

(22) PCT Filed: Jun. 20, 2007
(86) PCT No.: PCT/IT2007/000439

§ 371 Date: Dec. 17, 2009

(51) Int. Cl. H01L 31/042; H01L 31/00

(52) U.S. Cl. 136/244; 136/256; 136/255

(57) ABSTRACT

A photovoltaic module (1) and modular panel having at least one semiconductor element (7) with a photovoltaic effect, at least one electrical energy conversion circuit (9) generated by at least one photovoltaic semiconductor element (7), electrical connector (10) with at least one external electrical circuit and mechanical fixing (6) to the anchoring structure (4).

This application for a patent concerns a photovoltaic module and modular panel made with it to collect radiant solar energy and its transformation into electrical energy.

The construction of solar panels using more than one photovoltaic cell for the conversion of radiant solar energy into electrical energy has been known for many years.

The principle at the basis of photovoltaic solar cells can be summarised briefly as follows.

A photovoltaic cell is essentially similar to the junction of a semiconductor diode and differs from a normal diode not only for the size, but also because it is built in a way which allows the incident radiation (usually solar light) to reach the depletion layer of the potential barrier. An incident photon on a semiconductor has a chance of being absorbed if its energy is equal to or greater than the difference of energy between the valence band and that of conduction of the semiconductor itself.

A photon absorbed in the depletion layer of the junction has a high chance of generating an electron/hole pair which is separated and transported by the existing difference of potential towards the anode and cathode electrodes respectively, generating an electrical current in the external circuit connected to the two electrodes.

The recombination occurs by reclosure through an external circuit in which the electrical current thus generated can carry out a work. The optimisation of the efficiency of a junction to maximise the photovoltaic effect must take account of a plurality of parameters such as the transparency of the electrode turned towards the light source, the thickness of the semiconductor, the thickness of the depletion layer, the choice of an appropriate doping of the semiconductor to have the required values of the valence and conduction bands, and many others. These principles are widely known and dealt with in scientific and technical literature which should be referred to for any further information.

Current technology for the production of photovoltaic electrical energy is mainly based on silicon cells which are basically made with the same technology as that used for producing the components used in many different fields of electronics. The characteristic parameters of the individual constituent cell of all the photovoltaic elements produced on silicon are defined by the technology, resulting in an open circuit voltage of about 0.55V and an absorption peak around the wavelength of about 800-900 nanometres, generating a current of around 0.5 mA/mm² with a standard illumination of 1000 W/m² of radiant energy.

In the current state of technology, the maximum energy efficiency of a photovoltaic element made with this type of technology normally is not greater than 21-22% and the total efficiency of the installation normally is not higher than about 17%.

The technology for the production of photovoltaic solar cells today is relatively consolidated although in further evolution and is mainly based on cells in monocrystalline or polycrystalline silicon, even though other technologies have been demonstrated and available. In particular, are of a certain interest the cells made by amorphous silicon, because they are relatively economic but have a low efficiency in operation, and cells which use semiconductor materials other than silicon, such as gallium arsenide, cadmium telluride or germanium, which have a better performance but a relatively high cost. There is also a certain interest in the cells based on organic materials but, today, these are still mostly at the research stage and rather afar from possible industrial applications.

In the most common cases, solar cells are assembled in panels containing a certain number of cells (usually from 18 to 96 and more) and further connected together in series in groups of 10 to 20 panels, to create the source of electrical energy (string) with output voltage of 300V, 500V or higher.

If a connection to the electricity network is furthermore required, it's necessary a converter circuit (inverter) which transforms the unidirectional electrical energy generated by the photovoltaic source to the alternating voltage adapted for value and frequency to the parameters of the general electricity network.

Although very promising, development of the production of electrical energy from a photovoltaic source essentially meets the main obstacles in the high cost of cells made by mono crystalline or polycrystalline silicon, and in the aesthetic problem of the panels which are difficult to integrate in the aesthetics of buildings, particularly in those for civil use.

A further problem which is especially felt by designers and installers of equipment is the poor level of standardisation in both the size and features of photovoltaic panels, this makes costly and difficult the later replacement of defective elements in a plant built some years before.

The main purpose of this invention is the construction of a photovoltaic module free of the disadvantages indicated above.

Following this invention, a photovoltaic module is built which is rugged, reliable and cheap to produce, and which, at the same time, has a shape and size that offers scalability and modular features for the installation in which it will be included, through the construction of a monolithic photovoltaic module made preferably, but not necessarily, at least partially by ceramic or vitreous material and having an aesthetic aspect which is easy to integrate into coating or covering structures made by traditional materials and which integrate the photovoltaic element, the protective circuits and the electronic ones for the conversion of electrical energy, and the anchoring means into a monolithic structure.

A further purpose of this invention is that of make a solar panel made by a plurality of modules, which external face imitates the size and shape of ceramic tiles normally used for coating of building's façades.

A further purpose of this invention is that of make a solar panel made by a plurality of modules, such to imitate the typical outline of the tiles traditionally used for roofs, to promote aesthetic and functional integration with normal, non-photovoltaic tiles.

In the same way, can also be imitated in the shape and colour other traditional coverings, such as curved roof tiles, slate sheets, etc.

The known techniques available in the field of manufacturing ceramic or vitreous materials allow to obtain shapes and colours which makes it easy to imitate most traditional covering materials, or invent new ones. As a result, there is not will to go into too specific detail of the possible specific aesthetic solutions, while the discussion will concentrate on the manufacturing technique of the photovoltaic element and its connections on the surface of a ceramic or vitreous substrate and the production technique which enables the cost to be kept relatively low.

In particular, as a not limiting example, the photovoltaic elements integrated on ceramic described here are preferably of a size that makes them compatible with commercial tiles and roof tiles currently use in the construction industry.

In this perspective, the basic elementary format of the photovoltaic module in question is of an indicative size of about 300×300 mm for the elements for coating façades (tiles) and about 330×420 mm for those for covering (roof tiles).

In order to simplify the further description and drawings, reference is made to a square unit of about 300×300 mm, considering that the description can easily be extended to create similar modules of different sizes and shapes. The photovoltaic module, according to this invention, consists of a bearer structure preferably in ceramic material which integrates a photovoltaic element divided into an appropriate number of photovoltaic cells and the relative electrical connections into the part turned to the exterior, and has an energy converter and the relative connection means and fixing means in the rear part so that use, even by people with relatively few qualifications is relatively easy on the basis of simple instructions given by the technical staff. It's also described the technique for producing the photovoltaic element on ceramic elements of a similar shape and size to those used in traditional building work, such as tiles for coating façades and tiles for covering slope of roofs.

The mechanical support for the creation of the device which is the subject of this invention is preferably an easily produced substrate made by cheap materials, such as those currently in use in the ceramics industry, on which the photovoltaic element is created by means of the Chemical Vapour Deposition (CVD) technology, well-known in itself.

The manufacture of thin film photovoltaic solar cells has already been described, for example by Huang Yong Li (CN1547259 and CN1547263), and Huang Wen Chiang and Wu L. W. (US2003113481). However, in the cases cited, the use of very pure special ceramics has always been described. Barnett, in U.S. Pat. No. 5,057,163, describes the manufacture of a photovoltaic element on a ceramic substrate, interposing a metal barrier to prevent the chemical pollution of the semiconductor by the impurities of the substrate, but making the semiconductor by high temperature (1410° C.) fusion.

The photovoltaic module according to this invention, is different from those known because it is monolithic and integrates the support structure, photovoltaic element, electronic circuits for protection and voltage conversion and fixing means, all in a single monolithic module.

In addition, the photovoltaic module according to this invention is made with a method which allows high productivity and the solution to the problem of the liberation of the undesirable substances existing in traces in ceramic material, which could pollute the semiconductor material during the high temperature processes used in the technology known to date.

The ceramic currently used in building for coatings is a mixture of numerous hydrated silicates and oxides in varied proportions. The greatest percentage in weight is usually made up of Al₂O₃ but it also contains a number of other compounds which, although appearing with a lesser percentages, are a determining factor in the final aesthetic and mechanical features of the product.

Because of the uncertain composition of the basic material, the semiconductor material cannot, unfortunately, be deposited directly on an inert substrate, like a ceramic support, as some compounds, in particular the phosphors and arsenics ones which are usually present in traces in the base clayey material, would make the semiconductor unusable if it was mobilised during the diffusion processes.

It is also necessary to choose a support material with thermal expansion features which are relatively similar to those of silicon to prevent the breakage of the photovoltaic element when the module is subject to considerable temperature changes both during manufacture and in use when exposed to the sun and bad weather. Crystalline silicon has a linear temperature expansion factor of about 3.6×10⁻⁶ m/m ° C. Many of the most common ceramic and vitreous materials advantageously have a linear thermal expansion factor which is quite close to this value, in particular those which contain a high percentage, by weight, of SiO₂ and Al₂O₃, for example the commercial ceramic with 85% Al₂O₃ has a linear expansion factor of about 5.5×10⁻⁶ m/m ° C. and common borosilicate glass (corresponding to an average composition of SiO₂=70-81%, B₂O₃=7-13%, Na₂O or K₂O=4-8%, Al₂O₃=2-7%) has a linear expansion factor of 4×10⁻⁶ m/m ° C.

As the aim of this invention is the manufacture of a modular panel easy to integrate and install in buildings, a first hypothesis considers that the optimal number of elementary cells for the photovoltaic element is from 8 to 16, thus generating a voltage of between 5 and 10 V. A surface of 300×300 mm corresponds to 0.09 m² which therefore offers a light-gathering capacity of about 90 W of radiant solar energy if correctly exposed in an optimal manner and, considering an overall conversion efficiency of 15%, it will therefore be able to supply about 13.5 W of peak electrical energy.

The energy converter circuit incorporated in the ceramic element will, therefore, supply a constant value output, in this not limiting example of about 36V, also giving protection against short circuits, overloads and atmospheric discharges with the advantageous feature of, if necessary, taking the individual module out of service in case of failure (which can then be replaced later) without interrupting the operation of the whole installation. This voltage value is low enough to be considered as intrinsically safe (SELV=Safety Extra Low Voltage). This, with the parallel connection of the modules, reduces the risks for the workers during installation.

A further advantage of the module made according to this invention is the better thermal insulation of the building which make use of this kind of tiles, because of the space between the modules and the supporting wall of the building.

### BRIEF DESCRIPTION OF THE DRAWINGS

This invention will now be described with reference to the attached drawings, which disclose a not limiting example of implementation in which:

FIG. 1 shows schematically the photovoltaic module according to this invention, seen from the front side and fixed to an anchoring structure.

FIG. 2 shows schematically the photovoltaic module of FIG. 1, seen from the back side.

FIG. 3 is the detailed section of a preferred solution of the anchorage means of the photovoltaic module to the relative anchoring structure.

FIG. 4 is an enlarged section, not to scale, of the photovoltaic module according to this invention, which highlights the most important construction elements of the active surface.

FIG. 4a is an enlarged detail of FIG. 4.

FIG. 5 shows a block diagram of the voltage converter.

FIG. 6 shows a block diagram of the photovoltaic panel, consisting of more than one module and the relative electrical connections.

FIG. 7 is an enlargement of FIG. 1

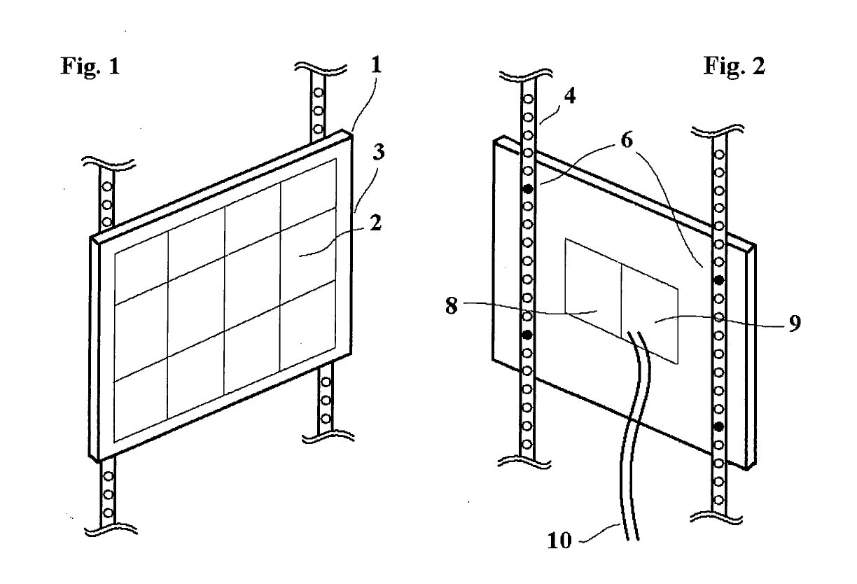

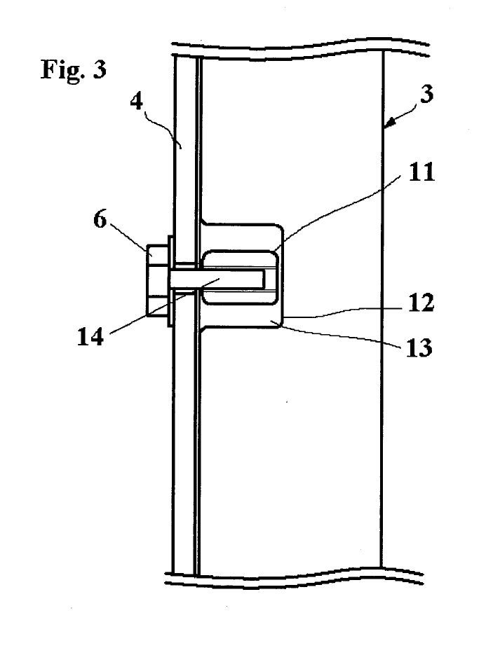

With reference to the said figures, with number (1) is indicated in the whole a monolithic photovoltaic module suitable for gathering radiant luminous energy and its conversion into electrical energy. In its most general constitution, module (1) includes:
an active surface (2) into which the photovoltaic element (7) constituting at least one photovoltaic cell (5) is incorporated;
a support structure (3);
fixing means (6) for its easy fixing to the relative anchorage structure (4).
an electronic circuit (9) for the protection of the module and electrical energy conversion, and the relative means of electrical connection (10);

The said mechanical support structure (3) is preferably made by ceramic material and has a square shape of about 300×300 mm, with the active surface (2) toward to the exterior side, and capable to receive light and convert it into electrical energy.

In a cavity preferably placed in the back side of said support (3) there is a place (8) for the electronic circuit (9) which has both the functions of protects the module and voltage converter.

The same support (3) has the fixing means (6) at the back, which allows anchorage to the anchoring structure (4).

The electronic circuit (9) has electrical connections (10, 20) which allow the connection of each module (1) at least partially in parallel with the other modules (1) composing the photovoltaic panel and to the electrical energy accumulation means not shown, or any voltage converter (21) which adapts the voltage and frequency of the electrical energy generated to values suitable for use on an external network (22).

The support (3) of the photovoltaic module (1) consists of an element in ceramic material preferably made by moulding a damp clayey paste and later drying it and baking it in a furnace.

Alternatively, the support (3) can be made in other materials, in particular, a vitreous material.

As further alternative possible but not preferred, the support (3) can be made by wide range of other possible materials, like concrete, or moulded thermoplastic or thermo-hardened resins.

In the not limiting example described, the external part has a surface which is roughly flat and smooth, while the internal part has suitable means for mechanical fixing (6) with modular features and at least one place (8) suitable for house an electronic circuit (9) for protecting the module and converting the electrical energy, and the related means (10) of electrical connection.

In particular, the means of mechanical fixing (6) to the anchoring structure (4) could conveniently be obtained, for example, with metal threaded inserts (11) locked in proper hollows (12) in the ceramic support (3) using appropriate resins (13), for example Araldite. Threaded bolts (14) are used in the said threaded inserts (11) for the mechanical fixing to the anchoring structure (4). In other shapes made, not shown, alternative fixing means (6) could be, for example, inserts or bolts or clamping systems locked into appropriate housing or incorporated in the ceramic support by mechanical means or through a suitable resin, for example Araldite, or they could be made directly in the ceramic material of the support (3).

Although this solution is considered less effective, the anchoring structure (4) can be made so that it can incorporate or also act by itself as electrical connection lines (20) to the external connection means (10) of the module (1) for connection to the accumulation systems not shown or the inverter (21).

The active surface (2) of the photovoltaic module (1) includes a photovoltaic element (7) made up of at least one photovoltaic cell (5), and preferably a number of cells (5) between nine and sixteen, preferably interconnected in series.

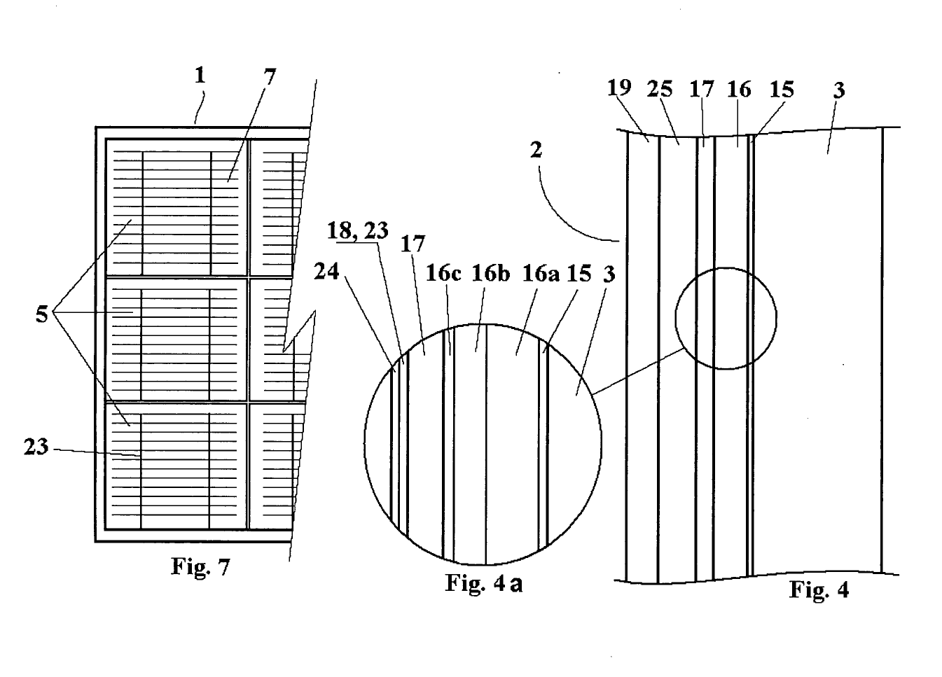

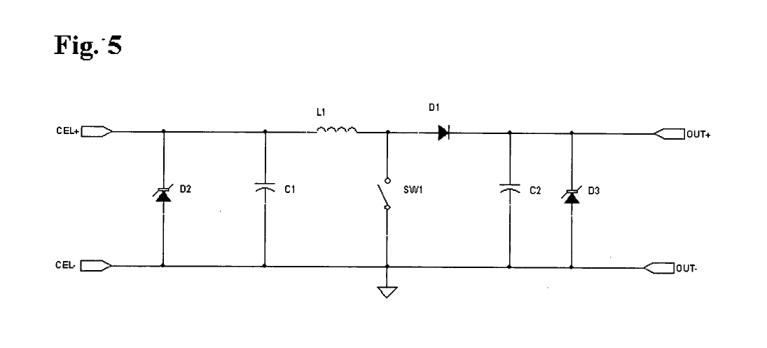

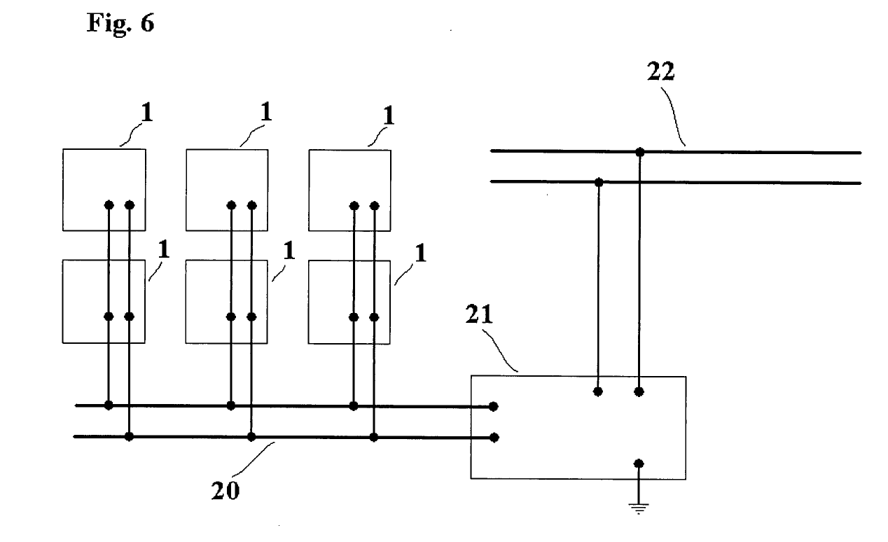

In order to permit the later galvanic plating processes, the ceramic or vitreous substrate forming the support (3) is made conductor with the formation of a conductor film (15) adhering to the said support (3), as shown in FIG. 4a.

In the preferred embodiment, in case the support (3) is made by a material having an hydrophilic surface, the conductor film (15) can suitably be constituted by manganese dioxide; in case the support (3) is made by a material having an hydrophobic surface, the conductor film (15) can suitably be constituted by carbon nanotubes.

On the said ceramic or vitreous substrate forming the support (3), made conductive by the film (15), a first metal plating (16a), preferably in copper, is growth in a galvanic manner, which, at the same time, forms both the base for the creation of the electrodes of the individual photovoltaic cells and the necessary connections between them. Because of the high purity of metal which can be growth by galvanic deposition, the said first metal plating (16a) also carries out the supplementary function of chemically insulating the active semiconductor (17) layers from the ceramic support (3) which is supposed to be relatively rich in unwanted impurities.

A second metal plating (16b), preferably in nickel, is deposited in a galvanic manner on the first metal plating (16a). It has the mechanical function of supplying an adequate support for the semiconductor material (17) making up the photovoltaic element (7).

If necessary, a third metal plating (16c), preferably in gold or another noble metal, is deposited in a galvanic or chemical manner on the second metal plating (16b). This has the possible function of chemically protecting the surface of the second plating, in addition to the possible function of supplying a crystalline grating with an appropriate atomic centre distance for the crystalline growth of the semiconductor (17) material making up the photovoltaic element (7).

The semiconductor elements are made as a thin film obtained through chemical deposition in the vapour phase of silicon of an appropriate purity into which carefully controlled quantities of impurities of elements from the third and fifth groups of the Periodic Table, like arsenic or phosphorus (fifth group) and aluminium or boron (third group), are introduced. The above elements are deposited on the surface of the selective metal platings (16a, 16b and 16c) making up the rear electrode. They are then connected together via a transparent electrode (18) made from a mixture of metal oxides like indium and tin, preferably with a composition of about 90% indium oxide (In₂O₃) and 10% tin oxide (SnO₂), commonly known as ITO, or a layer of carbon nanotubes, and possibly by a further selective metal plating (23) forming a grid that covers about 5% of the surface of the active area of each elementary cell (5) making the photovoltaic element (7).

Lastly, the semiconductor element (17) can be protected by a transparent layer (24) like, for example, polymethylmethacrylate (PMMA) or silicon nitride.

In the not limiting example suggested, starting from the ceramic or vitreous support (3) having a thickness of several millimetres and preferably between 1 and 20 millimetres, the sequence of layers is:
a first conductor layer (15), about some hundred nanometres thick, preferably made up of manganese dioxide (MnO2) or carbon nanotubes;
a second layer of copper (16a) having a thickness of about 10 micrometers and preferably between 1 and 50 micrometers;
a third layer of nickel (16b) about 10 micrometers thick and preferably between 1 and 50 micrometers;
if necessary a fourth layer of gold (16c), about one micrometer thick and preferably between 0.05 and 10 micrometers;
a layer (17) of semiconductor making at least one photovoltaic junction, preferably made of silicon in crystalline or microcrystalline or amorphous form, having a thickness between several tens and several hundreds of nanometers, and having a thickness preferably between 10 and 400 nanometres;
a transparent conductor electrode (18) of indium and tin oxide (ITO), onto which a further selective metal plating of aluminium (23) is added preferably with a thickness between 0.1 and 20 micrometers;
a further transparent protective layer (24) of polymethylmethacrylate (PMMA) or silicon nitride.

The active surface (2) of the photovoltaic module (1) is preferably protected by a further suitable transparent mechanical protection, preferably made up of a glass sheet (19) appropriately fixed to the structure of the ceramic substrate (3), for example by sealing the edges with a suitable polyester, polyurethane or silicon resin not shown.

It is appropriate to leave a space (25) between the glass sheet (19) and the photovoltaic complex (15, 16, 17, and 18).

To optimise optical efficiency, this space (25) should preferably be filled with a transparent material with a refraction index midway between that of the glass sheet (19) and that of the transparent protective layer (24) of the electrode (18) or, to make manufacturing easier, it could be filled by at least one gas, for example nitrogen (N₂) at a pressure near to that of the environment.

In practice, as it is the glass sheet (19) that the PMMA making up the layer (24) protecting the transparent electrode (18) that has a refraction index of about 1.45, the choice will preferably fall on a filling material with a refraction index near to this value.

In the preferred and disclosed solution, the semiconductor (17) making up the active element of the photovoltaic element (7) is made as a thin film, preferably through deposition in the silicon vapour stage obtained by decomposition at high temperature from a silane gas (Si:H), as explained more clearly below.

A different configuration is possible in case the support (3) is made by glass. In this case it is possible to use the side turned towards the support (3) as active surface (2) of the semiconductor (17) which constitutes the photovoltaic element (7) because the support (3), being transparent, can be turned towards the light source.

In a different configuration possible not shown, the semiconductor (17) which constitutes the above photovoltaic element (7) can be made up of traditional commercial photovoltaic cells in silicon or other semiconductor materials, like gallium arsenide, cadmium telluride or germanium, etc. fixed to the ceramic or vitreous support (3) similarly to that currently in use in the construction of photovoltaic panels in which the assembly of the photovoltaic cells on a support (printed circuit board) made by copper plated TEDLAR film or similar, is made by the usual techniques by lamination, of soft soldering with low temperature soldering alloy, or by electrically conductor resins or adhesives. The voltage converter circuit (9) can be made using known topologies, as not limiting example the boost, the quasi resonant, the flyback or the Sepic are all well known voltage converter topologies suitable to configure an inductor input booster circuit, intrinsically short-circuit and overload safe.

A detailed description of a converter of that type is not necessary as it is widely known to technicians skilled in the sector.

The booster configuration with inductive input and, in particular, in the configuration known as CURRENT MODE, gives some significant advantages:
the intrinsic safety against the risk of short circuit as the energy transmitted to the output at each cycle cannot exceed the maximum that can be accumulated in the inductor during the conduction stage of the switch element;
an output diode protects the circuit and the relative photovoltaic element from the circulation of inverse current if there is an imbalance in the photovoltaic system, for example, as happens when part of the cells (5) making up photovoltaic element (7) are illuminated by solar light and others are in shadow.
Because of the relatively low voltage generated by the cells in the disclosed module, the use of a step-up configuration allows to obtain an higher voltage and lower current more suitable for the easy connection of some modules in parallel making up a solar panel.

For these reasons, a system which adopts a BOOST type converter on each photovoltaic element enables easy connection of parallel elements on the same load, keeping the work voltage of the installation relatively low and, therefore, safer for operators.

The voltage converter circuit (9) can be adequately made separately with well known technologies, in the not limiting example can be adopted the configuration of a BOOST type switched voltage converter. A block diagram of this is circuit disclosed in FIG. 5.

If a ceramic type material is used as support (3), any technician skilled in the sector is able to create a support (3) in the shape and size required, for example a rough square with a relatively flat, smooth external surface to host the photovoltaic elements, and the rear surface capable to accommodate the electronic circuit (9), fixing means (6) and the means of connection (10), with the normally known moulding techniques of a damp clayey paste and subsequent drying, baking and known processing.

Appropriately sized holes for number and diameter to tolerate the expected current will be arranged in the predetermined points in which the electrical connection between the front surface hosting photovoltaic element (7) and the rear surface hosting electronic circuit (9) and the means of connection (10) are wanted.

If the surface of the ceramic support (3) is hydrophilic, the conductor layer (15) necessary for the subsequent galvanic processes can be easily obtained through a film of manganese dioxide, as is current practice in the printed circuit and thick film hybrid circuit industry. The latter is obtained through the reaction of a sodium or potassium permanganate in a watery solution, with the addition of small quantities of additives and pH correctors if necessary, on an organic substance, for example, glucose, previously adsorbed in the porosity of the ceramic support (3).

If the ceramic surface of the support (3) is hydrophobic, like in some vitreous ceramics (gres ceramics), the conductor layer (15) can be easily obtained by spraying and drying a colloidal solution of carbon nanotubes.

Similarly, if a glass is used as a support (3), any technician in the sector is able to create a support (3) of the shape and size required, as described above, with the normal known hot-moulding or casting and processing techniques.

In the preferred embodiment, when the support (3) is made of glass, the first conductor layer (15) can be deposited by spraying and drying a colloidal solution of carbon nanotubes.

In a possible but not preferred variant, the first conductor layer (15) can be deposited by vacuum evaporation or sputtering of metal with techniques known to the glass industry.

The ceramic or vitreous support (3) made conductive on the surface via the layer (15) is therefore connected to the anodic circuit of a galvanic cell and covered by a layer of copper about ten microns thick through treatment in copper salt solutions with a copper cathode.

In another possible construction variant, the ceramic or vitreous support (3) can be coated directly from the copper layer (16a). This is done by simply gluing the copper sheet to the surface of the support (3). In this case, the conductive layer (15) does not have to be created before.

Similarly to what is currently made in the technique known for the manufacture of printed circuits, a protective layer can be applied to the support (3). Usually, laminating a dry film photo-resist is preferred for this purpose but paints applied for screen-printing or with other means can be used. Depending on the optimisation of the production process, more than one technique can be used at the same time, for example, protection of the surface can be obtained by applying a spray paint on the back of the support (3) and with a photo-resist on the front.

For application of said photo-resist, the drawing of the circuit relating to the sub-division of the photovoltaic element in the individual solar cells for their connection is obtained through photographic exposure and the subsequent development with known techniques

It is important to note that, because of its natural porosity, a ceramic type support (3) must be protected on the entire surface or by the copper-plated surface or by appropriate covering materials, both to prevent absorption of the chemical and galvanic baths by the ceramic material and to avoid the release of pollutants and dust during the processes.

The copper-plated support (3), protected on the surface by the photo-resist can, therefore, be connected to the anodic circuit of a galvanic cell and be covered for subsequent treatments by a layer of nickel about ten microns thick. The nickel layer can be further covered by a layer of gold about one micron thick through galvanic or chemical processes widely used in an industrial context.

At this point, the first photo-resist is removed and the unnecessary copper is eliminated by chemical attack; the conductive and insulating areas are, therefore, defined on the surface of the support (3), creating selective plating which is more or less similar to a printed circuit board.

A further mask is then applied via a photo-resist, so that only the areas relating to the active surface of the individual cells (5) making up the photovoltaic element (7) are left uncovered, this areas coinciding with the rear electrode of the cells (5).

According to the preferred embodiment, the semiconductor material is deposited using the technique known as vapour deposition using special machines. This is a process carried out in conditions of relatively low pressure of about 10⁻⁴-10⁻⁵ Torr, when a gas containing the required substances condenses in a crystalline form on the exposed metal surface. Use of silane gas (Si:H), if necessary mixed with hydrogen (H₂), is preferred to obtain deposition of the semiconductor which will form the photovoltaic element (7). For decomposition on a tungsten wire at high temperature, the silane gas decomposes into silicon in the atomic state and hydrogen. As a result, the silicon is deposited on the exposed metal surfaces of the support. Careful adjustment of the work parameters is essential in order to obtain a deposition of silicon in a crystalline form with the right size of grain. A percentage of 20% silane and 80% hydrogen, and a deposition temperature of between 280 and 500° C. have been identified as optimal conditions for the process.

During the same silicon deposition operation, dopants are added for the creation of two different polarity N and P of semiconductors material. Dopants are made by controlled quantities of impurities of elements from the third and fifth groups of the Periodic Table, like arsenic or phosphorus (fifth group) and aluminium or boron (third group)

To optimise the efficiency, the profile of the junction has preferably a degree of doping, from the anode electrode to the cathode, before progressively decreasing then nothing, then progressively increasing in the opposite direction, which maximises the active area of photonic capture and, hence, the efficiency of conversion of the photovoltaic effect of the semiconductor element.

Silicon in an amorphous form can be deposited in a variation of the process which is not preferred; recrystallisation can then be obtained through a brief exposure to a high temperature. This can be economically obtained by applying a paste based on silicon in the SiC form, for example, through screen-printing and, after drying, recrystallisation is obtained at a relatively low temperature keeping the ceramic support at a temperature of about 500° C. and exposing the surface of the silicon to laser pulses of an appropriate strength to obtain recrystallisation of the semiconductor.

However, direct deposition of silicon in a crystalline form is preferred as the operation is simpler even if relatively slower.

As is known in semiconductor technology, and photovoltaic solar cells in particular, still working in vacuum and at relatively low temperatures of a few hundred degrees centigrade, a conductor layer (18) of transparent indium and tin oxides (ITO) and a further selective metal plating of aluminium or silver (23) making up a grid of connections which create the external electrode of each cell (5) making up the semiconductor element on the external surface of the semiconductor can be deposited by sputtering; the external surface can subsequently be protected by a further layer (24) of transparent resin like PMMA applied by evaporation of monomers.

In possible alternative solutions, the transparent electrode (18) can be a layer of carbon nanotubes, the selective metal plating (23) can be created through galvanic deposition of copper or gold and the external surface protected by a layer (24) of other materials like silicon nitride or other types of transparent synthetic resins, for example, silicone resins.

1. A photovoltaic solar module (1) for the uptake of radiant luminous energy and its transformation into electrical energy, comprising:
at least one semiconductor element (7) with a photovoltaic effect,
at least one electrical energy conversion circuit (9) generated by at least one photovoltaic semiconductor element (7) from a first voltage value determined by the physical features of the photovoltaic element and the radiation conditions to a second voltage having a preset value,
connection means (10) with at least one external electrical circuit, and
means (6) of fixing to an anchoring structure (4) all in a single structure supported by a ceramic or vitreous support (3), characterized in that said module (1) further comprises:
a conductor film (15) formed on the surface of said ceramic or vitreous support (3), and
at least a metal plating (16) growth in a galvanic manner on said conductor film (15), said metal plating (16) acting as a chemical barrier between the support (3) and the photovoltaic semiconductor element (7), wherein said semiconductor element (7) is a thin film deposited on said metal plating (16), by means of the technique of vapour deposition (CVD).

2. A photovoltaic solar module according to claim 1 in which said support (3) is made of a material having an hydrophobic surface and said conductor film (15) is constituted by carbon nanotubes.

3. A photovoltaic solar module according to claim 1 in which said support (3) is made of a material having an hydrophilic surface and said conductor film (15) is constituted by manganese dioxide.

4. A photovoltaic solar module according to claim 1 in which at least one semiconductor element (7) with a photovoltaic effect is made up to silicon in a single- or poly-crystalline or amorphous form, appropriately doped with at least one element from the third group and one from the fifth group of the Periodic Table.

5. A photovoltaic solar module according to claim 1, in which at least one semiconductor element (7) with a photovoltaic effect is made up of at least one semiconductor other than silicon, such as gallium arsenide, cadmium telluride or germanium, a silicon-germanium alloy, or a succession of at least two of the above semiconductor materials, appropriately doped with at least one element from the third group and one from the fifth group of the Periodic Table.

6. A photovoltaic solar module according to claim 1, in which said metal plating (16) acting as a barrier is made up of at least one layer (16a) of copper between 1 and 50 microns thick.

7. A photovoltaic solar module according to claim 6, in which the metal plating (16) acting as a barrier is made up of a first layer (16a) of copper between 1 and 50 microns thick and a second layer of nickel (16b) between 1 and 50 microns thick.

8. A photovoltaic solar module according to claim 7, in which the metal plating (16) acting as a barrier is made up of a first layer (16a) of copper between 1 and 50 microns thick, a second layer of nickel (16b) between 1 and 50 microns thick and a third layer (16c) of gold between 0.05 and 10 microns thick.

9. A photovoltaic solar module according to claim 1, in which said metal plating (16) acting as a barrier has the shape and size to be able to constitute the rear electrode of the photovoltaic element (7), and contributes to make up the electrical connections of the elementary cells (5) constituting the photovoltaic element (7).

10. A photovoltaic solar module according to claim 1, characterised in that it comprises at least one conversion circuit (9) of the electrical energy generated by at least one photovoltaic semiconductor element (7) from a first voltage value determined by the physical features of the photovoltaic element and the radiation conditions to a second preset voltage, said conversation circuit (9) incorporating a switched mode, inductive input, booster circuit and relative means of a control and protection.

11. A photovoltaic solar module according to claim 10, in which said conversion circuit (9) is a switched mode voltage converter inductive input booster with a no-load output voltage of the same equal or less than 42.4V.
